(19) United States
(12) Patent Application Publication
(10) Pub. No.: US 2025/0079313 A1
(43) Pub. Date: Mar. 6, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Cian-Yu Chen, Taichung City (TW); Chin-Lung Chung, Taoyuan City (TW); Yun-Chi Chiang, Hsinchu City (TW); Han-Tang Hung, Taipei City (TW); Meng-Pei Lu, Hsinchu City (TW); Shin-Yi Yang, New Taipei City (TW); Ming-Han Lee, Taipei City (TW); Ching-Fu Yeh, Hsinchu City (TW)

(73) Assignee: Taiwan Semiconductor Manufacturing Company, Ltd., Hsinchu (TW)

(21) Appl. No.: 18/460,594

(22) Filed: Sep. 4, 2023

(51) Int. Cl. H01L 23/532; H01L 21/768

(52) U.S. Cl. CPC H01L 23/53238; H01L 21/76843; H01L 21/76856; H01L 23/53233; H01L 23/5226

(57) ABSTRACT

A semiconductor structure including a first dielectric layer and a conductive pattern is provided. The conductive pattern is disposed in the first dielectric layer, wherein the conductive pattern comprises an alloy layer and a first conductive layer, the alloy layer surrounds sidewalls and a bottom surface of the first conductive layer, a material of the alloy layer comprises an alloy of at least two metals, and at least one of the at least two metals relative to the rest of the at least two metals tends to be reacted with a dielectric material of the first dielectric layer.

### BACKGROUND

As the semiconductor industry introduces new generations of integrated circuits (ICs) having higher performance and greater functionality, the density of the elements that form the ICs is increased, while the dimensions and spacing between components or elements of the ICs are reduced. The structure of metal wiring layers also becomes complex and minimized. To fabricate the metal wiring layers, a dual damascene process usually has been used. However, as the dimensions and spacing between components or elements are reduced, using the dual damascene process may raise up the gap-fill concern.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are schematic cross-sectional views of various stages in a manufacturing method of a semiconductor structure in accordance with some embodiments of the present disclosure.

FIG. 2 is schematic cross-sectional view of a semiconductor structure in accordance with some alternative embodiments of the present disclosure.

FIG. 3 is schematic cross-sectional view of a semiconductor structure in accordance with some alternative embodiments of the present disclosure.

FIG. 4 is schematic cross-sectional view of a semiconductor structure in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

The semiconductor structures 100, 200, 300 and 400 are provided for illustration purposes and do not necessarily limit the embodiments of the present disclosure to any number of devices, any number of regions, or any configuration of structures or regions. Furthermore, in some embodiments, each of the semiconductor structures 100, 200, 300 and 400 may be an intermediate structure fabricated during processing of a device (e.g., an IC) or a portion thereof, that may comprise static random access memory (SRAM) and/or logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, other memory cells, and combinations thereof.

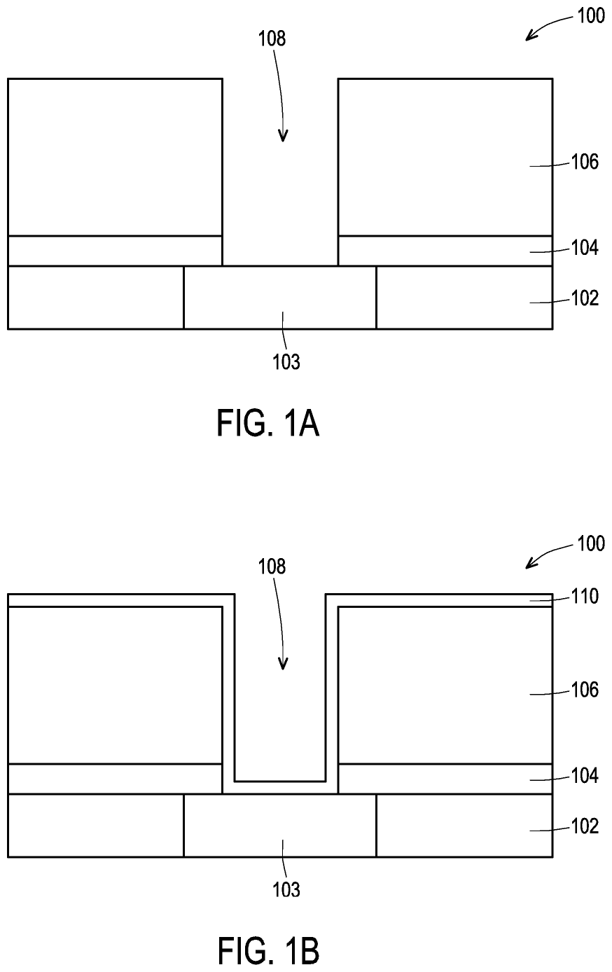

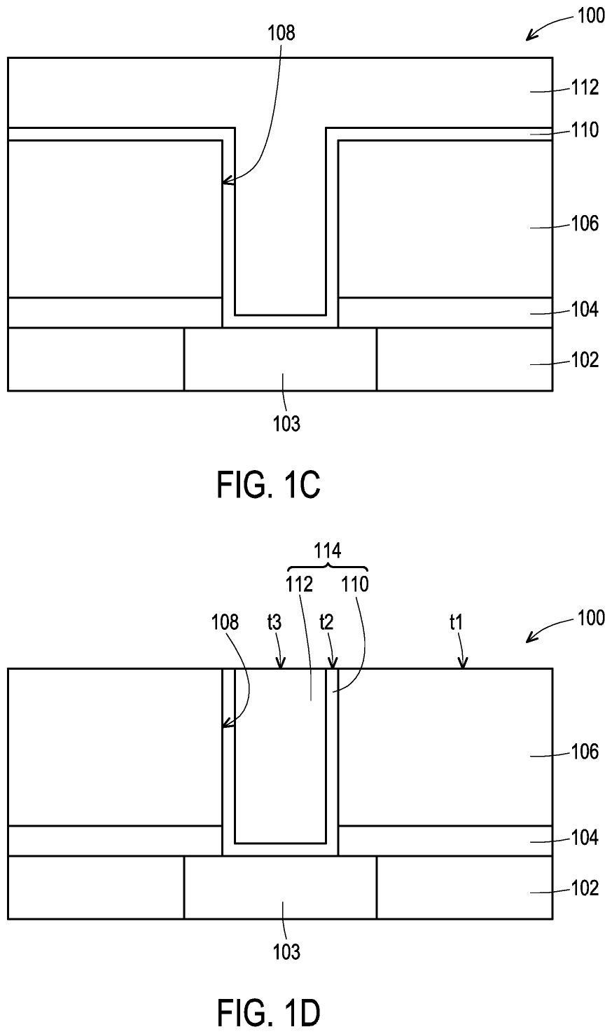

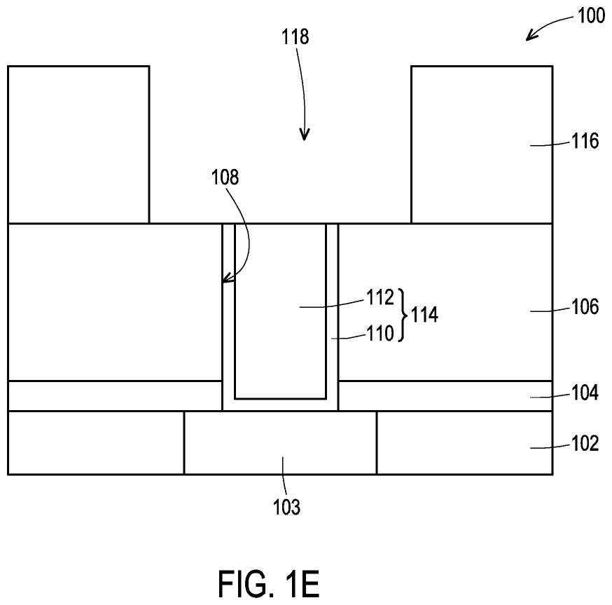

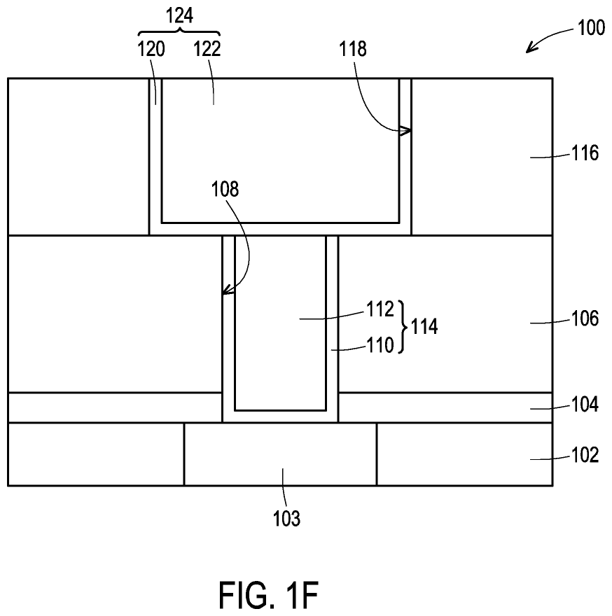

FIG. 1A to FIG. 1F are schematic cross-sectional views of various stages in a manufacturing method of a semiconductor structure 100 in accordance with some embodiments of the present disclosure.

Referring to FIG. 1A, a dielectric layer 102 is formed, and a conductive layer 103 is formed in the dielectric layer 102. In some embodiments, the dielectric layer 102 may be made of a low-k dielectric material. In some embodiments, the low-k dielectric material is generally a dielectric material having a dielectric constant (k-value) lower than about 4.5. For example, the dielectric layer 102 may be made of a low-k dielectric material having a k-value lower than about 2.3, which is sometimes referred to as an extra low-k (ELK) dielectric material. Examples of the low-k dielectric material may include tetraethylorthosilicate (TEOS) oxide (i.e., silicon oxide (SiO₂) formed from TEOS), un-doped silicate glass, or doped silicon oxide such as borophosphosilicate glass (BPSG), fused silica glass (FSG), phosphosilicate glass (PSG), boron doped silicon glass (BSG). In some embodiments, the dielectric layer 102 may be formed by suitable fabrication techniques such as spin-on coating, chemical vapor deposition (CVD), low pressure chemical vapor deposition (LPCVD), plasma enhanced chemical vapor deposition (PECVD), high density plasma chemical vapor deposition (HDPCVD), flowable chemical vapor deposition (FCVD), atomic layer chemical vapor deposition (ALCVD) or physical vapor deposition (PVD). As shown in FIG. 1A, the dielectric layer 102 is illustrated as a bulky layer, but the disclosure is not limited thereto. In some alternative embodiments, the dielectric layer 102 may be constituted by multiple dielectric layers.

In some embodiments, the conductive layer 103 may be formed of copper (Cu), Cu alloy or other suitable metals. In some embodiments, the conductive layer 103 may be formed by suitable fabrication techniques such as sputtering, CVD or plating (e.g., electroplating or electro-less plating). In certain embodiments, the conductive layer 103 may be formed by a damascene process, such as a single damascene process. In some embodiments, a barrier layer (not shown) may be formed between the conductive layer 103 and the dielectric layer 102 to prevent the material of the conductive layer 103 from migrating into the dielectric layer 102. The material of the barrier layer includes tantalum (Ta), tantalum nitride (TaN), titanium (Ti), titanium nitride (TiN), cobalt-tungsten (CoW) or a combination thereof, for example. The barrier layer may be formed by suitable fabrication techniques such as CVD, atomic layer deposition (ALD) or PVD.

As shown in FIG. 1A, the illustrated top surface of the conductive layer 103 is a planar surface, and the illustrated top surface of the conductive layer 103 is substantially flush or coplanar with the illustrated top surface of the dielectric layer 102. However, the disclosure is not limited thereto. In some alternative embodiments, the illustrated top surface of the conductive layer 103 may be a curved surface (e.g. convex surface) from the illustrated top surface of the dielectric layer 102. That is, the illustrated top surface of the conductive layer 103 is not planar, and a portion of the conductive layer 103 protrudes from and is higher than the illustrated top surface of the dielectric layer 102.

In some embodiments, the conductive layer 103 is a part of an interconnect structure of the semiconductor structure 100. In view of this, the dielectric layer 102 may be referred to as an interlayer dielectric layer. In an embodiment, the conductive layer 103 is a contact (or plug) for a transistor source, drain, or gate terminal. In another embodiment, the conductive layer 103 is a metal-x (Mx) level interconnect layer (e.g., metal wire feature). For example, “x” may be 0, 1, 2, and so on. Although not shown, the conductive layer 103 is coupled to active and/or passive components in the substrate through underlying layers of the interconnect structure or through the terminals (e.g., source, drain, and gate contacts) of the active and/or passive components.

Continue referring to FIG. 1A, an opening 108 is formed in an etch stop layer 104 and a dielectric layer 106. The etch stop layer 104 is formed on the dielectric layer 102 and the conductive layer 103. The etch stop layer 104 functions for controlling the end point during subsequent etching processes. In some embodiments, the etch stop layer 104 is formed of silicon oxide, silicon nitride, silicon carbide, silicon oxynitride or combinations thereof. In some embodiments, the etch stop layer 104 has a thickness of about 10 angstroms to about 1000 angstroms. The etch stop layer 104 is formed through any of a variety of deposition techniques, including, LPCVD, atmospheric-pressure chemical vapor deposition (APCVD), PECVD, PVD, sputtering, and future-developed deposition procedures.

The dielectric layer 106 is formed on the etch stop layer 104. In some embodiments, the dielectric layer 106 may be made of a low-k dielectric material. In some embodiments, the low-k dielectric material is generally a dielectric material having a dielectric constant (k-value) lower than about 4.5. For example, the dielectric layer 106 may be made of a low-k dielectric material having a k-value lower than about 2.3. Examples of the low-k dielectric material may include TEOS oxide, un-doped silicate glass, or doped silicon oxide such as BPSG, FSG, PSG, BSG. In some embodiments, the dielectric layer 106 may include the same material as the dielectric layer 102. In some alternative embodiments, the materials of the dielectric layer 106 and the dielectric layer 102 may be different. In some embodiments, the dielectric layer 106 may be formed by suitable fabrication techniques such as spin-on coating, CVD, LPCVD, PECVD, HDPCVD, FCVD, ALCVD or PVD. As shown in FIG. 1A, the dielectric layer 106 is illustrated as a bulky layer, but the disclosure is not limited thereto. In some alternative embodiments, the dielectric layer 106 may be constituted by multiple dielectric layers.

In some embodiments, the dielectric layer 106 may be a nitrogen-containing layer, a carbon-containing layer, or a carbon-containing and nitrogen-containing layer for increasing corrosion resistance during a subsequent planarization process and/or increasing electromigration resistance. In an embodiment, the dielectric layer 106 is a silicon-containing and nitrogen-containing dielectric layer. In another embodiment, the dielectric layer 106 is a silicon-containing and carbon-containing dielectric layer. In yet another embodiment, the dielectric layer 106 is a silicon-containing, nitrogen-containing, and carbon-containing dielectric layer. In an embodiment, the dielectric layer 106 has a ratio by weight of carbon to silicon about equal or greater than 0.5. In another embodiment, the dielectric layer 106 has a ratio by weight of nitrogen to silicon about equal or greater than 0.3. In yet another embodiment, the dielectric layer 106 has a ratio by weight of carbon to silicon about equal or greater than 0.5 and a ratio by weight of nitrogen to silicon about equal or greater than 0.3.

The opening 108 exposes a portion of the conductive layer 103. The opening 108 is formed by performing photolithography and etching processes. In some embodiments, the opening 108 is formed by the following steps: forming a photoresist pattern (not shown) having an opening on the dielectric layer 106; patterning the dielectric layer 106 by using the photoresist pattern as an etching mask; removing the photoresist pattern; and then etching the etch stop layer 104 at the opening 108 to expose the underlying conductive layer 103. In some alternative embodiments, the photoresist pattern remains on the patterned dielectric layer 106 during the etching of the etch stop layer 104, and the photoresist pattern is removed after the etch stop layer 104 is etched. In some embodiments, the dielectric layer 106 is patterned by using a dry etching process. In some embodiments, the etch stop layer 104 is etched by using a dry etching process.

Referring to FIG. 1B, an alloy layer 110 is formed on the above-described structure to line the sidewalls and the bottom surface of the opening 108 and over the dielectric layer 106. The material of the alloy layer 110 includes an alloy of at least two metals, and at least one of the at least two metals relative to the rest of the at least two metals tends to be reacted with dielectric materials. In some embodiments, the at least one of the at least two metals is prone to diffuse to the interface between the alloy layer 110 and the dielectric layer 106 and/or the interface between the alloy layer 110 and the etch stop layer 104 to react with the dielectric materials of the dielectric layer 106 and/or the etch stop layer 104 to form a few of dielectric compound in the alloy layer 110. In view of this, the distribution of the at least one of the at least two metals may vary in gradient in the alloy layer 110. That is, the gradient concentration of the at least one of the at least two metals may be formed during the formation of the alloy layer 110. From another point of view, the dielectric compound is in-situ formed during the formation of the alloy layer 110. It is noted that since the dielectric compound is formed in the alloy layer 110, the part of the alloy layer 110 having the dielectric compound is able to function as a barrier to prevent metal element (e.g., Cu) in a subsequently formed conductive layer 112 (described hereinafter) from diffusing into the dielectric layer 106 and/or the etch stop layer 104, and the rest part of the alloy layer 110 is able to function as a liner for improving the adhesion of the subsequently formed conductive layer 112 to the dielectric layer 106 and/or the etch stop layer 104 and the thermal stability of the subsequently formed conductive layer 112. That is, by selecting the specific material of the alloy layer 110, the single layer of the alloy layer 110 is divided into two parts having different functions. In other words, by selecting the specific material of the alloy layer 110, the single layer of the alloy layer 110 is rendered to have two functions. However, the disclosure is not limited thereto. In some alternative embodiments, by selecting the specific material of the alloy layer 110, the single layer of the alloy layer 110 has different functions (e.g., barrier function and liner function) without dividing into two parts.

In some embodiments, the at least two metals are selected from Co, Ru, Ta, Ti, W, Mo, Zn, Al, Mn, Zr, Hf, Nb, V, Cr, Sc, Y and Si. For example, the material of the alloy layer 110 includes Co—Ta alloy, and Ta tends to be reacted with dielectric materials. In some embodiments, the material of the in-situ formed dielectric compound includes silicide-based dielectric material, oxide-based dielectric material, nitride-based dielectric material, carbide-based dielectric material or a combination thereof. In the case where the material of the alloy layer 110 includes Co—Ta alloy, the material of the dielectric compound may include TaSi, Ta₂O₅, TaO₂, TaC₂, TaN or a combination thereof. In some embodiments, the thickness of the alloy layer 110 ranges from about 5 Å to about 50 Å.

In some embodiments, the alloy layer 110 may be formed by suitable deposition techniques such as PVD, CVD or ALD. In one embodiment, during the deposition process, a single target or gas which includes the desired alloy material or the alloy precursor for the desired alloy material production is used in the chamber. For example, in the case where the material of the alloy layer 110 includes Co—Ti alloy, during the PVD process, a single target includes Co—Ti alloy or Co—Ti alloy precursor is used. In another embodiment, during the deposition process, at least two targets or gases which respectively include the desired metal materials or the precursor for the desired metal material production are provided, and the at least two targets or gases are alternately introduced into the chamber. For example, in the case where the material of the alloy layer 110 includes Co—Ti alloy, during the PVD process, a target includes Co or Co precursor and another target includes Ti or Ti precursor are provided, and the two targets are alternately introduced into the chamber. In yet another embodiment, during the deposition process, at least two targets or gases which respectively include the desired metal materials or the precursor for the desired metal material production are provided, and the at least two targets or gases are together introduced into the chamber. For example, in the case where the material of the alloy layer 110 includes Co—Ti alloy, during the PVD process, a target includes Co or Co precursor and another target includes Ti or Ti precursor are provided, and the two targets are together introduced into the chamber. In some embodiments, during the deposition process, the process temperature of the alloy layer 110 is less than 400° C.

Referring to FIG. 1C, a conductive layer 112 is formed over the alloy layer 110 to fill up the opening 108. In some embodiments, the conductive layer 112 is formed by suitable fabrication techniques such as PVD, CVD, ALD, an electro-chemical plating (ECP) process, or an eletroless depsotion (ELD) process. In some embodiments, the conductive layer 112 is formed of Cu alloy which includes at least one metal other than Cu selected from Mn, Nb, Zr, Al, Ti, Ru, Mo, W, Cr and Zn. In details, the at least one metal in the Cu alloy relative to Cu tends to be reacted with dielectric materials. That is, the at least one metal in the Cu alloy is prone to diffuse to the interface between the alloy layer 110 and the dielectric layer 106 and/or the interface between the alloy layer 110 and the etch stop layer 104 to react with the dielectric materials of the dielectric layer 106 and/or the etch stop layer 104 to form a few of additional dielectric compound in the alloy layer 110. As such, by selecting the specific material for the conductive layer 112, the ability of the alloy layer 110 to prevent Cu in the conductive layer 112 from diffusing into the dielectric layer 106 and/or the etch stop layer 104 is strengthen. Further, by selecting the specific material for the conductive layer 112 (i.e., doping at least one metal selected from Mn, Nb, Zr, Al, Ti, Ru, Mo, W, Cr and Zn), the film properties of the conductive layer 112 is enhanced. For example, the result of the electromigration test, time-dependent dielectric breakdown (TDDB) test and/or stress migration (SM) test of the conductive layer 112 is enhanced.

Referring to FIG. 1D, a planarization process is performed to remove portions of the conductive layer 112 and the alloy layer 110 over the dielectric layer 106. In details, the excess portions of the conductive layer 112 and the alloy layer 110 outside the opening 108 are removed to render a via pattern 114 of the interconnect structure in the opening 108. In view of this, the dielectric layer 106 in which the via pattern 114 is formed may be referred to as an interlayer dielectric layer. In an embodiment, the via pattern 114 is a part of a metal-x (Mx) level interconnect layer in the semiconductor structure 100. For example, “x” may be 0, 1, 2, and so on. Further, as shown in FIG. 1D, the via pattern 114 is In some embodiments, the thickness of the conductive layer 112 in the via pattern 114 ranges from about 50 Å to about 2000 Å.

In some embodiments, after the planarization process is performed, the illustrated top surface of the via pattern 114 and the illustrated top surface t1 of the dielectric layer 106 are substantially flush or coplanar with each other. That is to say, the illustrated top surface t2 of the conductive layer 112, the illustrated top surface t3 of the alloy layer 110 and the illustrated top surface t1 of the dielectric layer 106 are substantially flush or coplanar with each other. In some embodiments, the planarization process includes a chemical mechanical polishing (CMP) process or a mechanical grinding process. As shown in FIG. 1D, in the via pattern 114, the alloy layer 110 surrounds the sidewalls and bottom surface of the conductive layer 112. As mentioned from FIG. 1A to FIG. 1D, it is noted that the via pattern 114 is formed by using a single damascene process. As such, the opening 108 is a single damascene opening. And, since the opening 108 is a placeholder for the via pattern 114 of the interconnect structure, the opening 108 is also referred to as a via opening. It is noted that as the via pattern 114 is formed by using a single damascene process and the via pattern 114 includes only a single layer of the alloy layer 110, the volume for accommodating the conductive layer 112 is increased. As such, even the dimensions and spacing between components or elements are reduced, the gap-fill concern of the semiconductor structure 100 can be eliminated. Further, since the alloy layer 110 between the conductive layer 103 and the conductive layer 112 includes the alloy material of at least two metals, the resistance value of the semiconductor structure 100 can be reduced.

Referring to FIG. 1E, an opening 118 is formed in a dielectric layer 116. The dielectric layer 116 is formed on the dielectric layer 106 and the via pattern 114. In some embodiments, the dielectric layer 116 may be made of a low-k dielectric material. In some embodiments, the low-k dielectric material is generally a dielectric material having a dielectric constant (k-value) lower than about 4.5. For example, the dielectric layer 116 may be made of a low-k dielectric material having a k-value lower than about 2.3. Examples of the low-k dielectric material may include TEOS oxide, un-doped silicate glass, or doped silicon oxide such as BPSG, FSG, PSG, BSG.

In some embodiments, the dielectric layer 116 may be a nitrogen-containing layer, a carbon-containing layer, or a carbon-containing and nitrogen-containing layer for increasing corrosion resistance during a subsequent planarization process and/or increasing electromigration resistance. In an embodiment, the dielectric layer 116 is a silicon-containing and nitrogen-containing dielectric layer. In another embodiment, the dielectric layer 116 is a silicon-containing and carbon-containing dielectric layer. In yet another embodiment, the dielectric layer 116 is a silicon-containing, nitrogen-containing, and carbon-containing dielectric layer. In an embodiment, the dielectric layer 116 has a ratio by weight of carbon to silicon about equal or greater than 0.5. In another embodiment, the dielectric layer 116 has a ratio by weight of nitrogen to silicon about equal or greater than 0.3. In yet another embodiment, the dielectric layer 106 has a ratio by weight of carbon to silicon about equal or greater than 0.5 and a ratio by weight of nitrogen to silicon about equal or greater than 0.3. In some embodiments, the dielectric layer 116 may include the same material as the dielectric layer 106. In some alternative embodiments, the materials of the dielectric layer 116 and the dielectric layer 106 may be different.

In some embodiments, the dielectric layer 116 may be formed by suitable fabrication techniques such as spin-on coating, CVD, LPCVD, PECVD, HDPCVD, FCVD, ALCVD or PVD. As shown in FIG. 1E, the dielectric layer 116 is illustrated as a bulky layer, but the disclosure is not limited thereto. In some alternative embodiments, the dielectric layer 116 may be constituted by multiple dielectric layers.

The opening 118 is formed by performing photolithography and etching processes. In some embodiments, the opening 118 is formed by the following steps: forming a photoresist pattern (not shown) having an opening on the dielectric layer 116; patterning the dielectric layer 116 by using the photoresist pattern as an etching mask; and removing the photoresist pattern. In some embodiments, the dielectric layer 116 is patterned by using a dry etching process.

Referring to FIG. 1F, a wiring pattern 124 of the interconnect structure is formed in the opening 118. In details, the wiring pattern 124 is physically and electrically connected with the via pattern 114, and is laterally surrounded by the dielectric layer 116. Further, as shown in FIG. 1F, the wiring pattern 124 includes an alloy layer 120 and a conductive layer 122, and the alloy layer 120 surrounds the sidewalls and bottom surface of the conductive layer 122. In some embodiments, the wiring pattern 124 is formed by substantially the same or similar manner to the via pattern 114, and thus its detailed description is not repeated herein for simplicity. That is, as the via pattern 114, the wiring pattern 124 is also formed by using a single damascene process. As such, the opening 118 is a single damascene opening. And, since the opening 118 is a placeholder for the wiring pattern 124 of the interconnect structure, the opening 118 is also referred to as a wiring opening. Also, in some embodiments, the material of the alloy layer 120 is substantially the same or similar to the material of the alloy layer 110, and the material of the conductive layer 122 is substantially the same or similar to the material of the conductive layer 112, and thus the detailed descriptions are not repeated herein for simplicity. As such, for details or descriptions of the alloy layer 120 and the conductive layer 122 not iterated herein, please refer to the aforesaid embodiments.

Since the wiring pattern 124 of the interconnect structure is embedded in the dielectric layer 116, the dielectric layer 116 may be referred to as an interlayer dielectric layer. In an embodiment, the wiring pattern 124 is a part of a metal-x (Mx) level interconnect layer in the semiconductor structure 100. For example, “x” may be 0, 1, 2, and so on.

Still referring to FIG. 1F, in this manufacture stage, the semiconductor structure 100 including the dielectric layer 102 with the conductive layer 103 formed therein, the etch stop layer 104 over the dielectric layer 102, the dielectric layer 106 over the etch stop layer 104, the new and improved via pattern 114 that penetrates the dielectric layer 102 and the etch stop layer 104, is electrically connected with the conductive layer 103, and includes the alloy layer 110 having an alloy material of at least two metals including at least one metal relative to the rest tending to be reacted with dielectric materials and the conductive layer 112 surrounded by the alloy layer 110, the dielectric layer 116 over the dielectric layer 106, and the new and improved wiring pattern 124 that penetrates the dielectric layer 116, is electrically connected with the via pattern 114, and includes the alloy layer 120 having an alloy material of at least two metals including at least one metal relative to the rest tending to be reacted with dielectric materials, and the conductive layer 122 surrounded by the alloy layer 120 is formed. Further, after the wiring pattern 124 is formed, the steps of FIG. 1A to FIG. 1F may be repeated to form one or more via pattern and one or more wiring pattern of the interconnect structure in the semiconductor structure 100.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure.

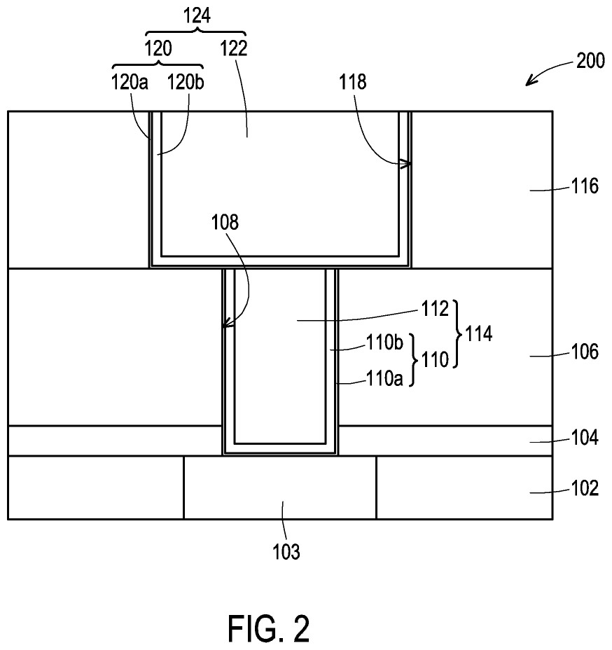

During the formation of the alloy layer 110 and/or the alloy layer 120, a treatment process is optionally performed. Hereinafter, other embodiments will be described with reference to FIG. 2.

FIG. 2 is schematic cross-sectional view of a semiconductor structure 200 in accordance with some alternative embodiments of the present disclosure. Referring to FIG. 2 and FIG. 1F, the semiconductor structure 200 illustrated in FIG. 2 is similar to the semiconductor structure 100 illustrated in FIG. 1F, hence the same reference numerals are used to refer to the same or liked parts, and its detailed description will be omitted herein. The differences between the semiconductor structure 200 illustrated in FIG. 2 and semiconductor structure 100 illustrated in FIG. 1F will be described below.

Referring to FIG. 2, in the semiconductor structure 200, the alloy layer 110 includes a sub layer 110a and a sub layer 110b, the sub layer 110a is disposed between the dielectric layer 106 and the sub layer 110b, and the sub layer 110b is disposed between the sub layer 110a and the conductive layer 112. That is, the sub layer 110a is closer to the dielectric layer 106 than the sub layer 110b.

In some embodiments, the sub layer 110a is formed by performed a treatment process on the alloy layer 110. During the formation of the alloy layer 110, in the case that the deposition process is performed by using a single target or gas, the deposition process is performed followed by the treatment process. During the formation of the alloy layer 110, in the case that the deposition process is performed by alternately introducing at least two targets or gases into the chamber in many cycles, the treatment process is performed after the first cycle of alternately introducing at least two targets or gases into the chamber is performed. During the formation of the alloy layer 110, in the case that the deposition process is performed by together introducing at least two targets or gases into the chamber, the deposition process is performed followed by the treatment process.

In some embodiments, the treatment process may be a plasma process or a soaking process. In some embodiments, the plasma process is configured to introduce one or more gases, precursors, atoms, ions, and/or radicals which respectively contain Si, O, N or C into the chamber to treat the alloy layer 110. In some embodiments, the soaking process is configured to introduce one or more gases and/or precursors which respectively contain Si, O, N or C into the chamber without forming plasma to treat the alloy layer 110. In some embodiments, the gas may include SiH₄, O₂, CO₂, NH₃, N₂, or CO. In some embodiments, the precursor may include any precursor that contains Si, O, N or C. In some embodiments, the precursor may include precursor complex comprised of ligand with N—, C(═O)—N—, COO—, O— or Si—. For example, the ligand may include amine ligand, amide ligand, carboxylate ligand, oxo ligand, or silyl ligand. In some embodiments, each of the atom, ion, and radical may be formed by performing a plasma dissociation process on the gas and/or precursor.

In an example, the treatment process is a SiH₄ plasma process, used to supply silicon for the bonds between the alloy layer 110 and silicon by flowing SiH₄ or precursor into a vacuum chamber. In another example, the treatment process is a NH₃ plasma process, used to supply nitrogen for the bonds between the alloy layer 110 and nitrogen by flowing NH₃ or precursor into a vacuum chamber. During the plasma process, any power supply capable of igniting and maintaining the plasma in the chamber may be utilized. In some embodiments, the power supply may be operated in any suitable form, such as direct current (DC), radio frequency (RF), pulsed DC, medium frequency (MF), and high-power impulse magnetron sputtering (HIPIMS). In some embodiments, the power range for the plasma process is between about 50 W to about 15 kW. In yet another example, the treatment process is a CO₂ soaking process, used to soak the alloy layer 110 by flowing CO₂ or precursor into a vacuum chamber without forming plasma.

It is noted that the one or more gases, precursors, atoms, ions, and/or radicals that respectively contain Si, 0, N or C are used to supply silicon, oxygen, nitrogen and/or carbon for the bonds between the alloy layer 110 and silicon, oxide, nitrogen and/or carbon. As mentioned above, relative to the rest of the at least two metals in the alloy layer 110, the at least one of the at least two metals in the alloy layer 110 is prone to diffuse to the interface between the alloy layer 110 and the dielectric layer 106 and/or the interface between the alloy layer 110 and the etch stop layer 104 to react with the dielectric materials of the dielectric layer 106 and/or the etch stop layer 104 to form the in-situ formed dielectric compound in the alloy layer 110. As such, during the treatment process, silicon, oxygen, nitrogen and/or carbon supplied by the one or more gases, precursors, atoms, ions, and/or radicals are prone to react with (e.g., bond to) the said at least one of the at least two metals in the alloy layer 110 to form one or more ex-situ formed dielectric compounds. That is, after the treatment process is performed, the sub layer 110a is formed to include both the in-situ formed dielectric compound and the ex-situ formed dielectric compound. In view of this, the sub layer 110a is able to prevent metal element (e.g., Cu) in the conductive layer 112 from diffusing into the dielectric layer 106 and/or the etch stop layer 104. As such, in the semiconductor structure 200, the sub layer 110a may be referred to as a barrier layer. From another point of view, during the formation of the alloy layer 110, by performing the treatment process, the part of the alloy layer 110 functioning as a barrier is visually formed as a layer, thereby strengthening the barrier ability of the alloy layer 110. In some embodiments, by controlling a reaction time, an operating temperature, an operating pressure, an applied energy, a flow rate, and/or any of other suitable operating parameters of the treatment process, the sub layer 110a with desirable thickness is obtained.

In some embodiments, the sub layer 110b includes the alloy material of at least two metals. That is, after performing the treatment process to form the sub layer 110a, the sub layer 110b is simultaneously formed. It is noted that the sub layer 110b is able to function as a liner layer for improving the adhesion of the conductive layer 112 to the dielectric layer 106 and/or the etch stop layer 104 and the thermal stability of the conductive layer 112. As such, during the formation of the alloy layer 110, by performing the treatment process, the alloy layer 110 becomes into multi-layer structure having different functions.

Continue referring to FIG. 2, in the semiconductor structure 200, the alloy layer 120 includes a sub layer 120a and a sub layer 120b, the sub layer 120a is disposed between the dielectric layer 116 and the sub layer 120b, and the sub layer 120b is disposed between the sub layer 120a and the conductive layer 122. That is, the sub layer 120a is closer to the dielectric layer 116 than the sub layer 120b. In some embodiments, the sub layer 120a and the sub layer 120b are formed by substantially the same or similar manner to the sub layer 110a and the sub layer 110b, and thus its detailed description is not repeated herein for simplicity. That is, as the sub layer 110a and the sub layer 110b, the sub layer 120a and the sub layer 120b are also formed by performing the treatment process.

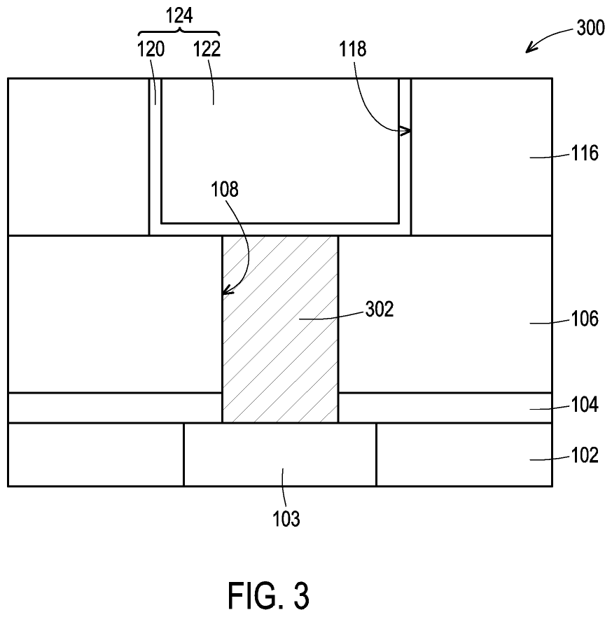

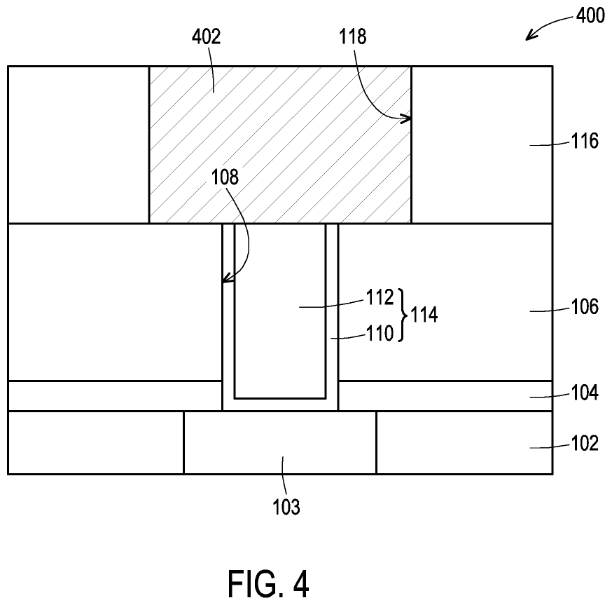

In the semiconductor structure 100 illustrated in FIG. 1F, both of the via pattern 114 and the wiring pattern 124 include one layer of alloy layer and one layer of conductive layer. However, the disclosure is not limited thereto. In some alternative embodiments, one of the via pattern 114 and the wiring pattern 124 may only include one layer of conductive layer. Hereinafter, other embodiments will be described with reference to FIG. 3 and FIG. 4.

FIG. 3 is schematic cross-sectional view of a semiconductor structure 300 in accordance with some alternative embodiments of the present disclosure. Referring to FIG. 3 and FIG. 1F, the semiconductor structure 300 illustrated in FIG. 3 is similar to the semiconductor structure 100 illustrated in FIG. 1F, hence the same reference numerals are used to refer to the same or liked parts, and its detailed description will be omitted herein. The differences between the semiconductor structure 300 illustrated in FIG. 3 and semiconductor structure 100 illustrated in FIG. 1F will be described below.

Referring to FIG. 3, in the semiconductor structure 300, a via pattern 302 is disposed in the opening 108. As shown in FIG. 3, the via pattern 302 is laterally surrounded by the dielectric layer 106 and the etch stop layer 104, and is in directly contact with the dielectric layer 106 and etch stop layer 104. As shown in FIG. 3, the via pattern 302 is physically and electrically connected with the wiring pattern 124. In details, the via pattern 302 is in directly contact with the alloy layer 120 of the wiring pattern 124. In some embodiments, the top surface of the via pattern 302 is substantially coplanar or flush with the top surface of the dielectric layer 106.

In some embodiments, the material of the via pattern 302 include metal, such as W, Cu, Ru, Ir, Ni, Os, Rh, Al, Mo, Co, alloys thereof, combinations thereof or any metal material with suitable resistance and gap-fill capability. In some embodiments, the formation of the via pattern 302 includes: forming a conductive material layer over the dielectric layer 102 to fill up the opening 108 and cover the top surface of the dielectric layer 106; and then performing a planarization process to remove portions of the conductive material layer over the dielectric layer 106, such that the top surface of the dielectric layer 106 is exposed. In some embodiments, the conductive material layer is formed by suitable fabrication techniques such as PVD, CVD, ALD, an ECP process, or an ELD process. In some embodiments, the planarization process includes a CMP process or a mechanical grinding process. In some alternative embodiments, the via pattern 302 is formed by performing a selective deposition process.

FIG. 4 is schematic cross-sectional view of a semiconductor structure 400 in accordance with some alternative embodiments of the present disclosure. Referring to FIG. 4 and FIG. 1F, the semiconductor structure 400 illustrated in FIG. 3 is similar to the semiconductor structure 100 illustrated in FIG. 1F, hence the same reference numerals are used to refer to the same or liked parts, and its detailed description will be omitted herein. The differences between the semiconductor structure 400 illustrated in FIG. 4 and semiconductor structure 100 illustrated in FIG. 1F will be described below.

Referring to FIG. 4, in the semiconductor structure 400, a wiring pattern 402 is disposed in the opening 118. As shown in FIG. 4, the wiring pattern 402 is laterally surrounded by the dielectric layer 116, and is in directly contact with the dielectric layer 116. As shown in FIG. 4, the wiring pattern 402 is physically and electrically connected with the via pattern 114. In details, the wiring pattern 402 is in directly contact with the alloy layer 110 and the conductive layer 112 of the via pattern 114. In some embodiments, the top surface of the wiring pattern 402 is substantially coplanar or flush with the top surface of the dielectric layer 116.

In some embodiments, the material of the wiring pattern 402 include metal, such as W, Cu, Ru, Ir, Ni, Os, Rh, Al, Mo, Co, alloys thereof, combinations thereof or any metal material with suitable resistance and gap-fill capability. In some embodiments, the formation of the wiring pattern 402 includes: forming a conductive material layer over the via pattern 114 and the dielectric layer 106 to fill up the opening 118 and cover the top surface of the dielectric layer 116; and then performing a planarization process to remove portions of the conductive material layer over the dielectric layer 116, such that the top surface of the dielectric layer 116 is exposed. In some embodiments, the conductive material layer is formed by suitable fabrication techniques such as PVD, CVD, ALD, an ECP process, or an ELD process. In some embodiments, the planarization process includes a CMP process or a mechanical grinding process. In some alternative embodiments, the wiring pattern 402 is formed by performing a selective deposition process.

In accordance with an embodiment, a semiconductor structure includes a first dielectric layer and a conductive pattern. The conductive pattern is disposed in the first dielectric layer, wherein the conductive pattern comprises an alloy layer and a first conductive layer, the alloy layer surrounds sidewalls and a bottom surface of the first conductive layer, a material of the alloy layer comprises an alloy of at least two metals, and at least one of the at least two metals relative to the rest of the at least two metals tends to be reacted with a dielectric material of the first dielectric layer.

In accordance with an embodiment, a semiconductor structure includes a first dielectric layer, an etch stop layer, a second dielectric layer and a via pattern. The first dielectric layer is with a first conductive layer formed therein. The etch stop layer is disposed over the first dielectric layer and the first conductive layer. The second dielectric layer is disposed over the etch stop layer. The via pattern penetrates the second dielectric layer and the etch stop layer and electrically connects with the first conductive layer, wherein the via pattern comprises a second conductive layer and a first alloy layer surrounding sidewalls and a bottom surface of the second conductive layer, a material of the first alloy layer comprises an alloy of at least two metals, and at least one of the at least two metals relative to the rest of the at least two metals tends to be reacted with dielectric materials of the second dielectric layer and the etch stop layer.

In accordance with an embodiment, a method of manufacturing a semiconductor structure includes at least the following steps. An opening extending through a first dielectric layer is formed. A single damascene process is performed to form a conductive pattern in the opening, wherein the conductive pattern comprises an alloy layer and a first conductive layer, the alloy layer surrounds sidewalls and a bottom surface of the first conductive layer, a material of the alloy layer comprises an alloy of at least two metals, and at least one of the at least two metals relative to the rest of the at least two metals tends to be reacted with a dielectric material of the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first dielectric layer; and
a conductive pattern disposed in the first dielectric layer, wherein the conductive pattern comprises an alloy layer and a first conductive layer, the alloy layer surrounds sidewalls and a bottom surface of the first conductive layer, a material of the alloy layer comprises an alloy of at least two metals, and at least one of the at least two metals relative to the rest of the at least two metals tends to be reacted with a dielectric material of the first dielectric layer.

2. The semiconductor structure according to claim 1, wherein the alloy layer is in directly contact with the first dielectric layer.

3. The semiconductor structure according to claim 1, wherein the at least two metals are selected from Co, Ru, Ta, Ti, W, Mo, Zn, Al, Mn, Zr, Hf, Nb, V, Cr, Sc, Y and Si.

4. The semiconductor structure according to claim 1, wherein a material of the first conductive layer includes Cu alloy including at least one metal selected from Mn, Nb, Zr, Al, Ti, Ru, Mo, W, Cr and Zn, wherein the at least one metal in the Cu alloy relative to Cu tends to be reacted with the dielectric material of the first dielectric layer.

5. The semiconductor structure according to claim 1, further comprising:
an etch stop layer disposed under the first dielectric layer and laterally surrounding the conductive pattern.

6. The semiconductor structure according to claim 1, further comprising:
a second dielectric layer disposed under the first dielectric layer; and
a second conductive layer disposed in the second dielectric layer and electrically connecting with the conductive pattern.

7. The semiconductor structure according to claim 6, wherein the conductive pattern is in directly contact with the second conductive layer.

8. A semiconductor structure, comprising:
a first dielectric layer with a first conductive layer formed therein;
an etch stop layer disposed over the first dielectric layer and the first conductive layer,
a second dielectric layer disposed over the etch stop layer; and
a via pattern penetrating the second dielectric layer and the etch stop layer and electrically connecting with the first conductive layer, wherein the via pattern comprises a second conductive layer and a first alloy layer surrounding sidewalls and a bottom surface of the second conductive layer, a material of the first alloy layer comprises an alloy of at least two metals, and at least one of the at least two metals relative to the rest of the at least two metals tends to be reacted with dielectric materials of the second dielectric layer and the etch stop layer.

9. The semiconductor structure according to claim 8, wherein the at least two metals of the first alloy layer are selected from Co, Ru, Ta, Ti, W, Mo, Zn, Al, Mn, Zr, Hf, Nb, V, Cr, Sc, Y and Si.

10. The semiconductor structure according to claim 8, wherein the material of the alloy layer includes Co—Ta alloy or Co—Ti alloy.

11. The semiconductor structure according to claim 8, wherein a material of the second conductive layer includes Cu alloy including at least one metal selected from Mn, Nb, Zr, Al, Ti, Ru, Mo, W, Cr and Zn, wherein the at least one metal in the Cu alloy relative to Cu tends to be reacted with the dielectric materials of the second dielectric layer and the etch stop layer.

12. The semiconductor structure according to claim 8, further comprising:
a third dielectric layer disposed over the second dielectric layer and the via pattern; and
a wiring pattern penetrating the third dielectric layer and electrically connecting with the via pattern, wherein the wiring pattern comprises a third conductive layer and a second alloy layer surrounding sidewalls and a bottom surface of the third conductive layer, a material of the second alloy layer comprises an alloy of at least two metals, and at least one of the at least two metals relative to the rest of the at least two metals tends to be reacted with a dielectric material of the third dielectric layer.

13. The semiconductor structure according to claim 12, wherein the at least two metals of the second alloy layer are selected from Co, Ru, Ta, Ti, W, Mo, Zn, Al, Mn, Zr, Hf, Nb, V, Cr, Sc, Y and Si.

14. The semiconductor structure according to claim 12, wherein a material of the third conductive layer includes Cu alloy including at least one metal selected from Mn, Nb, Zr, Al, Ti, Ru, Mo, W, Cr and Zn, wherein the at least one metal in the Cu alloy relative to Cu tends to be reacted with the dielectric material of the third dielectric layer.

15. A method of manufacturing a semiconductor structure, comprising:
forming an opening extending through a first dielectric layer; and
performing a single damascene process to form a conductive pattern in the opening, wherein the conductive pattern comprises an alloy layer and a first conductive layer, the alloy layer surrounds sidewalls and a bottom surface of the first conductive layer, a material of the alloy layer comprises an alloy of at least two metals, and at least one of the at least two metals relative to the rest of the at least two metals tends to be reacted with a dielectric material of the first dielectric layer.

16. The method according to claim 15, wherein the step of performing the single damascene process comprises:
forming the alloy layer lining sidewalls and a bottom surface of the opening and locating over the first dielectric layer;
filling up the opening with the first conductive layer; and
performing a planarization process to remove portions of the first conductive layer and the alloy layer over the first dielectric layer.

17. The method according to claim 16, wherein the step of forming the alloy layer comprises:
performing a deposition process to form the alloy layer; and
performing a treatment process on the alloy layer, wherein the treatment process is a plasma process or a soaking process.

18. The method according to claim 15, wherein the at least two metals of the alloy layer are selected from Co, Ru, Ta, Ti, W, Mo, Zn, Al, Mn, Zr, Hf, Nb, V, Cr, Sc, Y and Si.

19. The method according to claim 15, wherein a material of the first conductive layer includes Cu alloy including at least one metal selected from Mn, Nb, Zr, Al, Ti, Ru, Mo, W, Cr and Zn, wherein the at least one metal in the Cu alloy relative to Cu tends to be reacted with the dielectric material of the first dielectric layer.

20. The method according to claim 15, wherein a thickness of the alloy layer ranges from about 5 Å to about 50 Å.
